(19) United States
(12) Patent Application Publication
(10) Pub. No.: US 2010/0148272 A1
(43) Pub. Date: Jun. 17, 2010

(54) SEMICONDUCTOR DEVICE AND MANUFACTURING METHOD THEREOF

(76) Inventor: Kentaro EDA, Oita-ken (JP)

Correspondence Address: FINNEGAN, HENDERSON, FARABOW, GARRETT & DUNNER;LLP, 901 NEW YORK AVENUE, NW, WASHINGTON, DC, 20001-4413, US

(21) Appl. No.: 12/635,531

(22) Filed: Dec. 10, 2009

(30) Foreign Application Priority Data
Dec. 11, 2008 (JP) 2008-315561

(51) Int. Cl. H01L 27/092; H01L 21/8238

(52) U.S. Cl. 257/369; 438/216; 257/411; 257/E21.639; 257/E27.062

(57) ABSTRACT

A semiconductor device includes a semiconductor substrate having a first region including an n-type active element and a second region including a p-type active element, an element isolation region isolating plurality of the n-type active element and plurality of the p-type active element, a first insulating film having a tensile stress provided on the first region and on the element isolation regions of the second regions, and a second insulating film having a compression stress provided on the second region.

### CROSS-REFERENCE TO RELATED APPLICATION

This application is based upon and claims the benefit of priority from the prior Japanese Patent Application No. 2008-315561 filed on Dec. 11, 2008, the entire contents of which are incorporated herein by reference.

### BACKGROUND OF THE INVENTION

The present invention relates to a semiconductor device such as a CMOS-FET (Complementary Metal Oxide Semiconductor Field Effect Transistor) and a manufacturing method thereof.

In recent years, with miniaturization and sophistication of an electronic device and the like, for example, it has been attempted to increase carrier mobility in order to improve driving force in a CMOS-FET or the like constituting an SRAM (Static Random Access Memory) cell.

It is known that carrier mobility depends on stresses caused by the plane direction of a substrate used, the axial direction, a lattice distortion, or the like. The direction in which the carrier mobility is improved or deteriorated are different in an n-type MOS-FET using electrons as carriers and in a p-type MOS-FET using holes as carriers. For example, as disclosed in “C.-H. Ge et al., 8-10 Dec. 2003, pp. 3.7.1-3.7.4”, when the <110> axis direction of the (100) plane of an Si substrate is set as a channel length direction, carrier mobility can be improved by applying a tensile stress in an n-type MOS-FET and applying compression stress in a p-type MOS-FET in this direction (X direction) and a direction (Z direction) perpendicular to the substrate face and by applying a tensile stress in an n-type MOS-FET and a p-type MOS-FET in the channel width direction (Y direction).

Methods of applying stresses may include a method of forming an insulating film having a tensile stress or compression stress on an electrode as disclosed in Japanese Patent Application Laid-Open No. 2007-142104 (FIG. 1, etc.). By separately forming different elements, stresses adapted to the respective elements are applied.

However, in such a method, the number of processes increases due to separate formation of different insulating films. Moreover, to apply a sufficient stress, a thicker insulating film has to be formed. There is consequently a problem that the process margin at the time of formation of a contact hole and the like decreases.

### SUMMARY

According to an aspect of the present invention, there is provided a semiconductor device including a semiconductor substrate having a first region including an n-type active element and a second region including a p-type active element, an element isolation region isolating plurality of the n-type active element and plurality of the p-type active element, a first insulating film having a tensile stress provided on the first region and on the element isolation regions of the second regions, and a second insulating film having a compression stress provided on the second region.

According to another aspect of the present invention, there is provided a method of manufacturing a semiconductor device, including forming an element isolation region in a semiconductor substrate having a first region including the n-type active element and a second region including the p-type active element, forming the n-type active element in the first region and forming the p-type active element in the second region, forming a first insulating film having a tensile stress on the first region and on the element isolation region of the second regions, and forming a second insulating film having a compression stress on the second region.

### BRIEF DESCRIPTION OF THE DRAWINGS

FIG. 1 is a cross sectional view of a MOSFET cell in a semiconductor device according to an embodiment of the present invention;

FIGS. 2 to 4, 6, 8, and 10 are cross sectional views showing processes of manufacturing the MOSFET cell in the embodiment of the present invention;

FIGS. 5, 7, and 9 are top views showing processes of manufacturing the MOSFET cell in the embodiment of the present invention;

FIG. 11 is a diagram showing stress in a semiconductor device according to an embodiment of the invention;

FIGS. 12 and 13 are cross sectional views of a MOSFET cell in a semiconductor device according to an embodiment of the present invention.

### DETAILED DESCRIPTION

Reference will now be made in detail to the present embodiment of the invention, an example of which is illustrated in the accompanying drawings. Wherever possible, the same reference numbers will be used throughout the drawing to refer to the same or like parts.

An embodiment of the present invention will be described below with reference to the drawings.

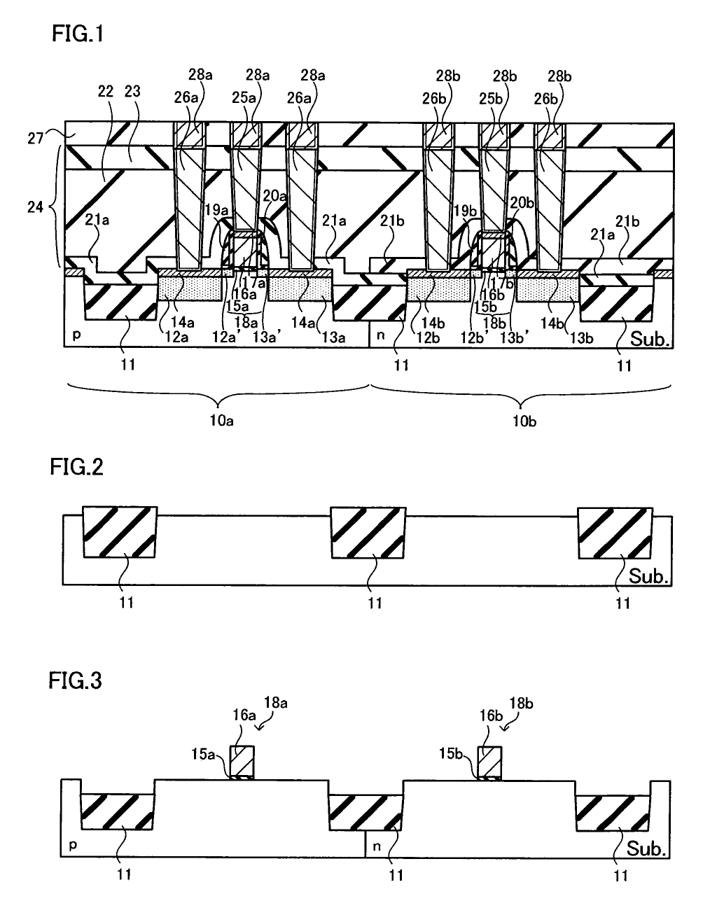

FIG. 1 is a cross sectional view of a MOSFET cell in a semiconductor device of the embodiment. An Si substrate (sub.) is used as a semiconductor substrate, and an n-MOSFET region 10a in which an n-type MOSFET as an n-type active element is formed and a p-MOSFET region 10b in which a p-type MOSFET as a p-type active element is formed are formed. The semiconductor substrate (sub.) is isolated by an STI 11 constructed by, for example, an LP (Low Pressure)-SiN film/a TEOS (Tetraethoxysilane) film/a TEOS film.

In the n-MOSFET region 10a and the p-MOSFET region 10b which are isolated, source regions 12a and 12b spaced from one another and drain regions 13a and 13b isolated from each other are formed, respectively. In the source region 12b and the drain region 13b in the p-MOSFET region 10b, an embedded SiGe layer (hereinbelow, referred to as e-SiGe layer) which is epitaxially grown is formed, and a compression stress is applied. On the surfaces of the source regions 12a and 12b and the drain regions 13a and 13b, silicide layers 14a and 14b are formed, respectively.

On a region sandwiched by the source region 12a and the drain region 13a, a gate electrode 18a formed of a polysilicon film 16a and a silicide layer 17a is formed with a gate insulating film 15a interposed between the region and the gate electrode 18a. On a region sandwiched by the source region 12b and the drain region 13b, a gate electrode 18b formed of a polysilicon film 16b and a silicide layer 17b is formed with a gate insulating film 15b interposed between the region and the gate electrode 18b. On sides of the gate electrode 18a, gate side walls formed of an insulating film 19a made of TEOS or the like and an LP-SiN film 20a are formed. On sides of the gate electrode 18b, gate side walls formed of an insulating film 19b made of TEOS or the like and an LP-SiN film 20b are formed. Under the gate side walls, LDDs (Lightly Doped Drain) 12a′, 12b′, 13a′, and 13b′ are formed.

On those layers, an interlayer 24 made of, for example, SiN films 21a and 21b, an insulating film 22 and an insulating film 23 is formed. A tensile stress is applied by the SiN film 21a, and a compression stress is applied by the SiN film 21b. On the STI 11 in the p-MOSFET region 10b, the SiN films 21a and 21b are sequentially stacked.

Via contacts 25a and 25b reaching the gate electrodes 18a and 18b, respectively, and via contacts 26a and 26b reaching the silicide layers 14a and 14b, respectively are formed so as to penetrate the interlayer film 24. Each of the via contacts 25a, 25b, 26a, and 26b is constructed by a barrier metal film made of titanium or the like and a metal film made of tungsten or the like.

Further, on the via contacts 25a, 25b, 26a, and 26b, interconnections 28a and 28b constructed by a barrier metal film made of Ti or the like and a Cu film which are isolated by an interlayer film 27 are formed.

Such a MOSFET cell is formed as follows.

First, as shown in FIG. 2, an SiN film (not shown) is formed in a thickness of, for example, 150 nm by the LPCVD (Low Pressure Chemical Vapor Deposition) method on the Si substrate (sub.). A resist film is coated on the SiN film and a resist pattern is formed by the lithography method. Using the resist pattern as a mask, the SiN film is etched by the RIE (Reactive Ion Etching) method. Further, the Si substrate (sub.) is etched by, for example, 300 nm, the resist pattern is removed, and an STI trench is thus formed.

Subsequently, an insulating film such as a TEOS film is deposited on the surface. After that, planarization is performed using the SiN film as a stopper by the CMP (Chemical Mechanical Polishing) method. Then, the insulating film is etched by, for example, about 100 nm. Further, the SiN film on the surface of the Si substrate (sub.) is removed by etching, thereby forming the STI 11.

As shown in FIG. 3, p-type and n-type impurities are injected into the Si substrate (sub.), and heat treatment at 1,000° C. or higher is performed, thereby forming device regions (well channel regions) of p-type and n-type. On the Si substrate (sub.), an insulating film which becomes the gate insulating films 15a and 15b is formed in a thickness of, for example, 1 nm. Further, a polysilicon film which becomes the polysilicon films 16a and 16b is formed in a thickness of, for example, 150 nm by the LPCVD method.

A resist film is applied on the polysilicon film and a resist pattern is formed by the lithography method. Using the resist pattern as a mask, the polysilicon is etched by the RIE method, the resist pattern is removed, and the polysilicon films 16a and 16b are formed. Further, the exposed insulating film is removed by wet etching, thereby forming the gate electrodes 18a and 18b.

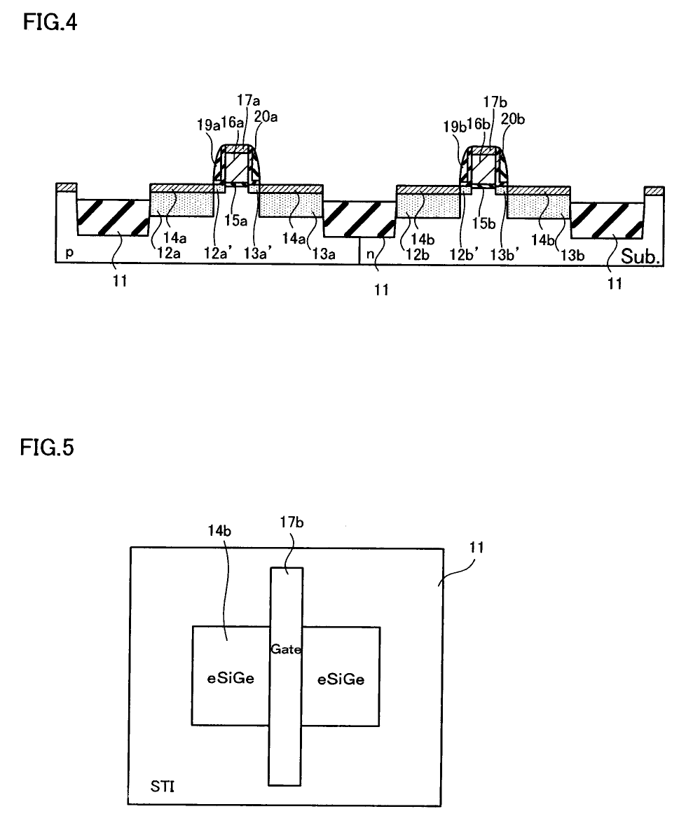

Subsequently, as shown in FIG. 4, by performing recess etching of digging the surface of the Si substrate (Sub.) in the n-type well channel region, a recess region is formed with a depth of, for example, about 100 nm. By epitaxially growing SiGe, an e-SiGe layer is formed. Impurities are injected into the p-type and n-type well channel regions, and heat treatment at, for example, 800° C. is performed, thereby forming the LDDs 12a′, 12b′, 13b′, and 13b′ as shallow impurity diffusion regions.

An insulating film made of TEOS or the like is formed on the surface in a thickness of, for example, 20 nm by the LPCVD method. After that, an SiN film is formed on the surface by the LPCVD method and etched back by the RIE method. In this manner, gate side walls formed of the insulating film 19a and the LP-SiN film 20a are formed on the sides of the gate electrode 18a, and gate side walls formed of the insulating film 19b and the LP-SiN film 20b are formed on the side faces of the gate electrode 18b.

Next, impurities are injected in the p-type and n-type well channel regions and heat treatment at, for example, 1,000° C. or higher is performed, thereby forming the source regions 12a and 12b and the drain regions 13a and 13b. Further, by the salicide technology, the silicide layers 14a, 14b, 17a, and 17b are selectively formed on the surface of the source regions 12a and 12b, the drain regions 13a and 13b, and the polysilicon films 16a and 16b. As a result, the structure of the p-MOSFET region 10b as shown in the top view of FIG. 5 is formed.

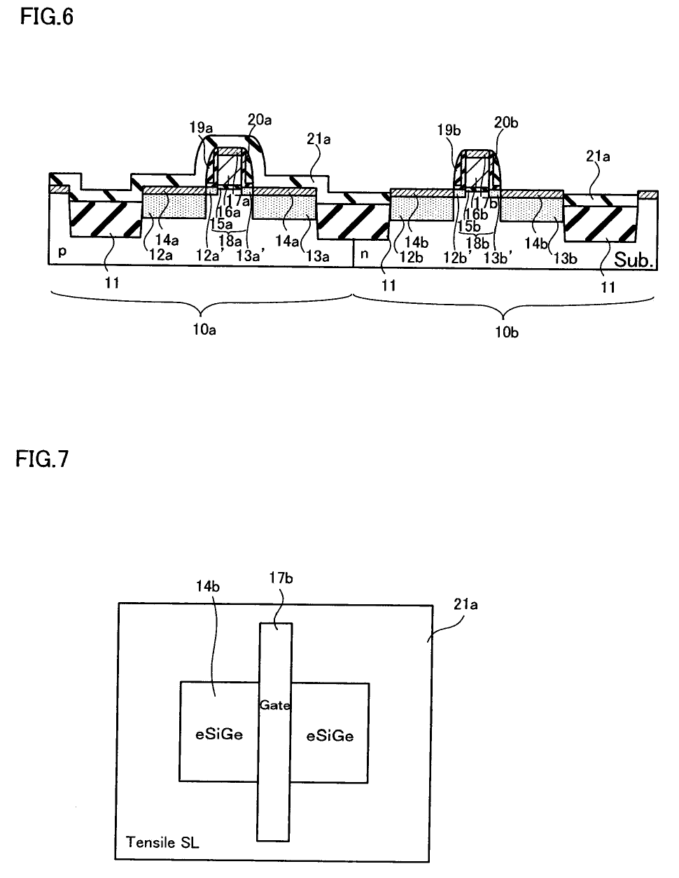

Subsequently, as shown in FIG. 6, by the plasma CVD method, an SiN film which becomes the SiN film 21a having a tensile stress is formed on the surface in a thickness of, for example, 60 nm. A resist is coated and is patterned so as to cover the n-MOSFET region 10a and the STI 11 in the p-MOSFET region 10b by the lithography method. The SiN film on the device region of the p-MOSFET region 10b exposed is removed and the resist is removed, thereby forming the structure of the p-MOSFET region 10b as shown in the top view of FIG. 7.

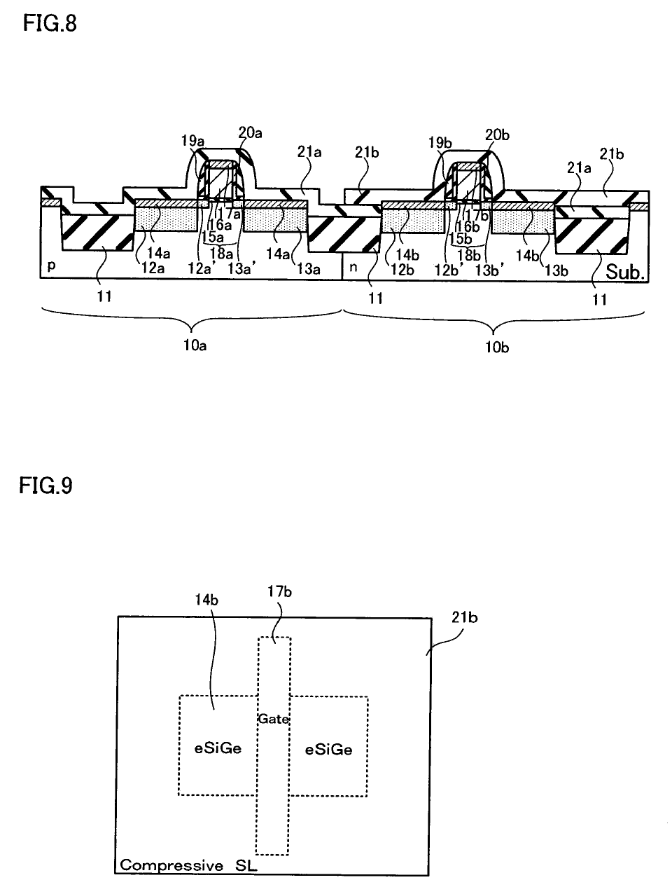

Further, as shown in FIG. 8, by the plasma CVD method, the SiN film 21b having a compression stress is formed in a thickness of, for example, 60 nm on the surface. A resist is applied and patterned so as to cover the p-MOSFET region 10b by the lithography method. The SiN film on the exposed n-MOSFET region 10a is removed. In this manner, a DSL (Dual Stress Liner) structure is formed, and the structure of the p-MOSFET region 10b as shown in the top view of FIG. 9 is formed.

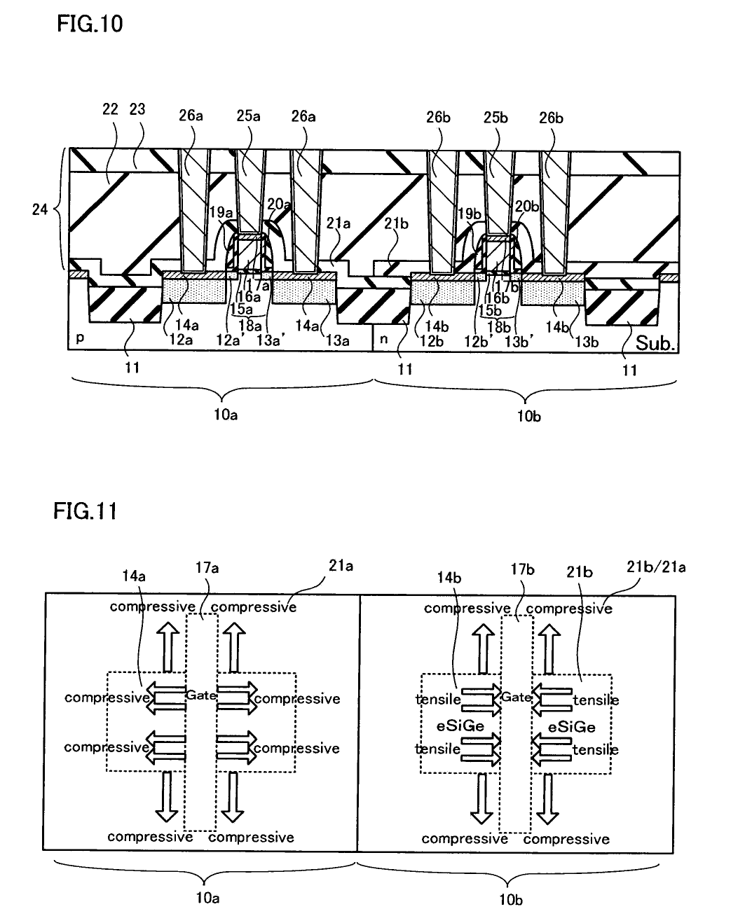

Subsequently, as shown in FIG. 10, an insulating film such as an SiN film is formed in a thickness of, for example, 400 nm on the SiN films 21a and 21b by the LPCVD method and planarized by the CMP method, thereby forming the insulating film 22. Further, by the plasma CVD method, the insulting film 23 such as a TEOS film is formed in a thickness of, for example, 200 nm on the insulating film 22.

A resist film is applied on the insulating film 23, and a resist pattern of the via contacts 25a, 25b, 26a, and 26b is formed by the lithography method. Using the resist pattern as a mask, the interlayer film 24 is etched by the RIE method. The resist pattern is removed, thereby forming contact holes.

The barrier metal film made of titanium or the like is formed in a thickness of, for example, 5 nm by sputtering method, a metal film made of tungsten or the like is formed in a thickness of 250 nm by the thermal CVD method, and the contact holes are buried. By removing the metal film and the barrier metal film on the insulating film 23 by the CMP method, the via contacts 25a, 25b, 26a, and 26b respectively reaching the silicide layers 14a, 14b, 17a, and 17b are formed in the via contact holes.

On the interlayer film 24 and the via contacts 25a, 25b, 26a, and 26b, an insulating film which becomes the interlayer film 27 is formed in a thickness of, for example, 200 nm by the plasma CVD method. A resist film is coated on the insulating film, and a resist pattern is formed by the lithography method. Using the resist pattern as a mask, the insulating film is etched by the RIE method, and the resist pattern is removed, thereby forming trenches.

Subsequently, a barrier metal film made of titanium or the like is formed in a thickness of, for example, 5 nm by the sputtering method, a Cu film is formed on the barrier metal film by plating, and the trench is buried. By removing the Cu film and the barrier metal film on the interlayer film 27 by the CMP method, the interconnections 28a and 28b formed of the barrier metal film and the Cu film are formed in the trenches.

In this manner, a semiconductor device as shown in FIG. 1 is formed. The semiconductor device obtained can be made to operate by applying a voltage to a metal pad formed on the interconnection.

As described above, on the n-MOSFET region 10a and on the STI 11 of the p-MOSFET region 10b, the SiN film 21a having a tensile stress is formed, an e-SiGe layer having a compression stress is formed in the device region of the p-MOSFET region 10b, and the SiN film 21b having a compression stress is formed on the p-MOSFET region 10b.

With such a structure, as shown in FIG. 11, the tensile stress is applied in the longitudinal direction of the gate electrode (channel width direction) in the n-MOSFET region 10a and the p-MOSFET region 10b, and the compression stress can be applied in the width direction of the gate electrode (channel length direction) in the device region in the p-MOSFET region 10b. Therefore, in each of the n-MOSFET region 10a and the p-MOSFET region 10b, the carrier mobility can be improved. The driving force in a semiconductor device such as a C-MOSFET can be improved.

Since two patterns are sufficient for masks for forming SiN films to apply stresses, the number of processes for separated formation does not increase. In addition, since the tensile stress can be applied also in the longitudinal direction of the gate electrode in the p-MOSFET region 10b, it is unnecessary to form a thicker insulating film in order to apply a sufficient stress.

In the embodiment, the SiN film formed by the plasma CVD method is used as a film for applying a tensile stress or a compression stress. However, the film is not limited to the plasma CVD film. For example, a thermal CVD film or an optical CVD film formed by thermal CVD or optical CVD other than plasma CVD may be used. In addition to the SiN film, a silicon oxide film, a silicon oxynitride film, a hafnium oxide film, an aluminum oxide film, an aluminum nitride film, a tantalum oxide film, or a titanium oxide film can be used as a single layer or in the form of a stack of two or more layers such as, for example, an SiN film/SiO₂ film/SiN film.

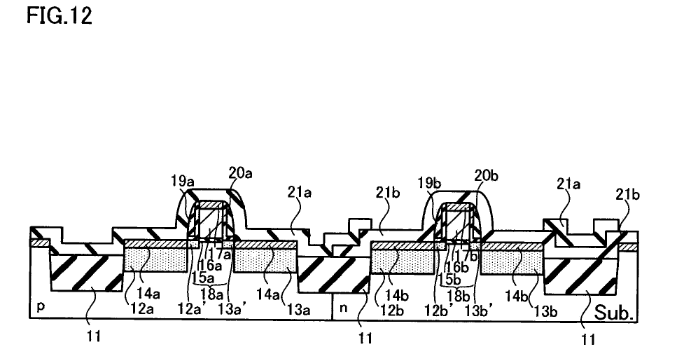

In the embodiment, as the SiN films formed on the STI 11 in the p-MOSFET region 10b, the SiN film 21a having the tensile stress is provided as a lower layer, and the SiN film 21b having the compression stress is provided as an upper layer. However, as shown in FIG. 12, the lower layer may be a film having the compression stress, and the upper layer may be a film having the tensile stress.

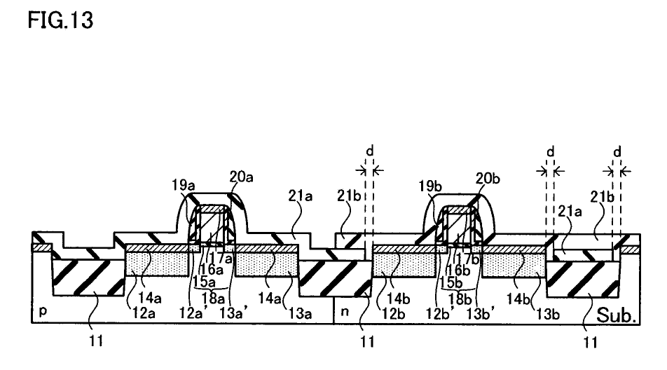

In the embodiment, the SiN film 20a having the tensile stress is formed so as to be aligned with the edge of the STI 11 in the p-MOSFET region 10b. However, it is sufficient that a film having the tensile stress is not formed on a p-type MOSFET device (on the source-drain region) so that the tensile stress is not applied to a lower part of the gate electrode. When misalignment is considered, preferably, as shown in FIG. 13, a film having the tensile stress is formed so as to be spaced from a p-type MOSFET device by, for example, a gap “d” of 20 nm or less.

As the semiconductor substrate, not only a bulk Si substrate used in the embodiment but also an SOI (Silicon On Insulation) substrate or the like may be used.

Other embodiments of the invention will be apparent to those skilled in the art from consideration of the specification and practice of the invention disclosed herein. It is intended that the specification and examples be considered as exemplary only, with a true scope and spirit of the invention being indicated by the following claims.

What is claimed is:

1. A semiconductor device comprising:
a semiconductor substrate having a first region including an n-type active element and a second region including a p-type active element;
an element isolation region isolating plurality of the n-type active element and plurality of the p-type active element;
a first insulating film having a tensile stress provided on the first region and on the element isolation regions of the second regions; and
a second insulating film having a compression stress provided on the second region.

2. The semiconductor device according to claim 1, wherein the p-type active element includes a source region and a drain region each having an SiGe epitaxial film.

3. The semiconductor device according to claim 1, wherein the p-type active element is subjected to a tensile stress in a longitudinal direction of a gate electrode and a compression stress in a width direction of the gate electrode.

4. The semiconductor device according to claim 1, wherein the n-type active element is subjected to a tensile stress in the longitudinal direction of a gate electrode.

5. The semiconductor device according to claim 1, wherein the second insulating film is provided on the first insulating film on the element isolation region in the second region.

6. The semiconductor device according to claim 1, wherein the first insulating film is provided on the second insulating film on the element isolation region in the second region.

7. The semiconductor device according to claim 1, wherein the first insulating film is formed to be spaced from the p-type active element.

8. The semiconductor device according to claim 1, wherein a gap “d” between the first insulting film and the p-type active element satisfies 0≦d≦20 (nm).

9. The semiconductor device according to claim 1, wherein at least either one of the first insulating film and the second insulating film is an SiN film.

10. The semiconductor device according to claim 1, wherein at least either one of the first insulating film and the second insulating film is a plasma CVD film.

11. The semiconductor device according to claim 1, wherein at least either one of the first insulating film and the second insulating film includes any of an SiN film, a silicon oxide film, a silicon oxynitride film, a hafnium oxide film, an aluminum oxide film, an aluminum nitride film, a tantalum oxide film, and a titanium oxide film.

12. The semiconductor device according to claim 1, wherein at least either one of the first insulating film and the second insulating film is formed of a single layer.

13. The semiconductor device according to claim 1, wherein at least either one of the first insulating film and the second insulating film is formed of a plurality of layers.

14. A method of manufacturing a semiconductor device, comprising:
forming an element isolation region in a semiconductor substrate having a first region including the n-type active element and a second region including the p-type active element;
forming the n-type active element in the first region and forming the p-type active element in the second region;
forming a first insulating film having a tensile stress on the first region and on the element isolation region of the second regions; and
forming a second insulating film having a compression stress on the second region.

15. The method of manufacturing a semiconductor device according to claim 14, wherein after the first insulating film is formed, the second insulating film is formed.

16. The method of manufacturing a semiconductor device according to claim 14, wherein after the second insulating film is formed, the first insulting film is formed.

17. The method of manufacturing a semiconductor device according to claim 14, further comprising:
a recess formed in a predetermined region in the second region,
SiGe epitaxial-grown in the recess to form an e-SiGe layer, and
impurities injected in the e-SiGe layer to form a source region and a drain region.

18. The method of manufacturing a semiconductor device according to claim 14, wherein the first insulating film is formed to be spaced from the p-type active element.

19. The method of manufacturing a semiconductor device according to claim 14, wherein a gap “d” between the first insulating film and the p-type active element satisfies 0≦d≦20 (nm).

20. The method of manufacturing a semiconductor device according to claim 14, wherein at least either one of the first insulating film and the second insulating film is formed by plasma CVD.
